(19) United States
(12) Patent Application Publication
(10) Pub. No.: US 2026/0324421 A1
(43) Pub. Date: Oct. 15, 2026

(54) SEMICONDUCTOR DEVICE AND METHOD OF MANUFACTURING THE SAME

(71) Applicant: Renesas Electronics Corporation, Tokyo (JP)

(72) Inventors: Hideaki TAMIMOTO, Tokyo (JP); Kazuki MATSUMURA, Tokyo (JP); Kanato GO, Tokyo (JP)

(21) Appl. No.: 19/467,450

(22) Filed: Feb. 2, 2026

(30) Foreign Application Priority Data
Feb. 3, 2025 (JP) 2025-016334

(51) Int. Cl. H10W 40/20; H10W 72/00; H10W 74/10; H10W 74/15; H10W 90/00

(52) U.S. Cl. CPC H10W 40/242; H10W 40/233; H10W 72/877; H10W 74/141; H10W 74/15; H10W 90/724; H10W 90/736

(57) ABSTRACT

A semiconductor device includes: a wiring substrate having an upper surface; a semiconductor chip having a front surface and a back surface opposite the front surface and mounted on the wiring substrate such that the front surface faces the upper surface; and a metal plate fixed onto the back surface of the semiconductor chip. The semiconductor chip includes: a plurality of protruding electrodes arranged on the front surface; and a metal film formed on the back surface. The metal plate is fixed onto the back surface of the semiconductor chip via a sintered metal layer formed on the metal film.

### CROSS-REFERENCE TO RELATED APPLICATIONS

The disclosure of Japanese Patent Application No. 2025-016334 filed on Feb. 3, 2025, including the specification, drawings and abstract is incorporated herein by reference in its entirety.

### BACKGROUND

The present embodiments relate to a semiconductor device and a method of manufacturing the same.

There are disclosed techniques listed below.

Patent Document 1 Japanese Unexamined Patent Application Publication No. 2022-81872

As a substrate product that can improve heat dissipation, there is a semiconductor device in which a lid is attached to a back surface of a semiconductor chip that is mounted on a wiring substrate (see Patent Document 1, for example) by flip-chip connection method.

### SUMMARY

In recent years, with the advancement and acceleration of the semiconductor device, the amount of heat generated from the semiconductor chip tends to increase. Therefore, as a part of improving the performance of the semiconductor device, further enhancement of heat dissipation in the semiconductor devices is required.

Other objects and novel features will become apparent from the description of this specification and the accompanying drawings.

A semiconductor device according to one embodiment includes: a wiring substrate having a first surface; a semiconductor chip having a second surface and a third surface opposite the second surface and mounted on the wiring substrate such that the second surface faces the first surface; and a first metal plate fixed onto the third surface of the semiconductor chip. The semiconductor chip includes: a plurality of protruding electrodes arranged on the second surface; and a first metal film formed on the third surface. The first metal plate is fixed onto the third surface of the semiconductor chip via a sintered metal layer formed on the first metal film.

A method of manufacturing a semiconductor device according to the one embodiment includes steps of: (a) preparing a wiring substrate having a first surface; (b) after the step of (a), mounting a semiconductor chip, which has a second surface, a plurality of protruding electrodes arranged on the second surface, a third surface opposite the second surface, and a first metal film formed on the third surface, on the wiring substrate such that the second surface faces the first surface; (c) after the step of (b), covering the semiconductor chip and the first surface of the wiring substrate with a sealing resin such that the first metal film is exposed from the sealing resin; (d) after the step of (c), performing a heat treatment on the sealing resin, and forming a sealing body; (e) after the step of (d), placing a metal particle layer containing a plurality of metal particles on the first metal film exposed from the sealing body; and (f) after the step of (e), placing a first metal plate on the metal particle layer.

A method of manufacturing a semiconductor device according to another embodiment includes steps of: (a) preparing a wiring substrate having a first surface; (b) after the step of (a), mounting a semiconductor chip, which has a second surface, a plurality of protruding electrodes arranged on the second surface, a third surface opposite the second surface, and a first metal film formed on the third surface, on the wiring substrate such that the second surface faces the first surface; (c) after the step of (b), covering the semiconductor chip and the first surface of the wiring substrate with a sealing resin such that the first metal film is exposed from the sealing resin; (d) after the step of (c), before fully curing the sealing resin, placing a metal particle layer containing a plurality of metal particles on the first metal film exposed from the sealing resin; (e) after the step of (d), placing a first metal plate on the metal particle layer; (f) after the step of (e), performing a heat treatment on the sealing resin and the metal particle layer so as to fully cure the sealing resin, and forming a sealing body and a sintered metal layer.

According to the above embodiment, the performance of the semiconductor device can be improved.

### BRIEF DESCRIPTION OF THE DRAWINGS

FIG. 1 is a top view of a semiconductor device according to one embodiment.

FIG. 2 is a bottom view of the semiconductor device shown in FIG. 1.

FIG. 3 is a plan view showing the state where components and the sealing body on the semiconductor chip shown in FIG. 1 are removed.

FIG. 4 is a cross-sectional view taken along line A-A of FIG. 1.

FIG. 5 is an explanatory diagram showing an example of the manufacturing process of the semiconductor device shown in FIG. 1.

FIG. 6 is a plan view showing an example of the wiring substrate prepared in the wiring substrate preparing step shown in FIG. 5.

FIG. 7 is a cross-sectional view showing the state where the semiconductor chip is mounted on the wiring substrate in the semiconductor chip mounting step shown in FIG. 5.

FIG. 8 is a cross-sectional view showing the state where underfill paste is filled between the semiconductor chip and the wiring substrate in the underfill filling step shown in FIG. 5.

FIG. 9 is a schematic cross-sectional view showing the state where the underfill paste is being cured in the underfill curing step shown in FIG. 5.

FIG. 10 is a cross-sectional view showing the state where sealing resin is filled in the molding die where the wiring substrate shown in FIG. 9 is placed in the sealing resin molding step shown in FIG. 5.

FIG. 11 is a schematic cross-sectional view showing the state where the sealing resin shown in FIG. 10 is cured to form the sealing body in the sealing resin molding step shown in FIG. 5.

FIG. 12 is a cross-sectional view showing the state where metal particle paste is placed on the metal film in the metal particle layer placement step shown in FIG. 5.

FIG. 13 is a cross-sectional view showing the state where a metal plate is placed on the metal particle layer before sintering in the metal plate placement step shown in FIG. 5.

FIG. 14 is a schematic cross-sectional view showing the state where the metal particle layer is heated to form a sintered layer in the sintering step shown in FIG. 5.

FIG. 15 is a schematic cross-sectional view showing the state where solder balls are placed on the lands of the wiring substrate and a reflow treatment is performed in the ball mounting step shown in FIG. 5.

FIG. 16 is an explanatory diagram showing a modified example of the manufacturing method for the semiconductor device shown in FIG. 5.

FIG. 17 is a top view of a modified example of the semiconductor device shown in FIG. 1.

FIG. 18 is a cross-sectional view along line B-B of FIG. 17.

### DETAILED DESCRIPTION

### EXPLANATION OF DESCRIPTION FORMAT, BASIC TERM, AND USAGE IN THIS APPLICATION

In this application, the description of embodiments is divided into multiple sections for convenience. These are not mutually independent and separate, but one is a part detail of the other, or one is a modified example of the other. In principle, descriptions of similar parts are omitted. Furthermore, each component in the embodiment is not essential unless clearly indicated as essential, theoretically limited in number, or obviously essential from the context.

Similarly, in the description of embodiments, materials, compositions, etc., even if stated as "X consisting of A", unless clearly limited or obviously limited from the context, elements other than A are not excluded. For example, regarding components, it means "X containing A as the main component". For example, even if referred to as "silicon member”, it is not limited to pure silicon but also includes SiGe (silicon-germanium) alloys and other multi-component alloys with silicon as the main component, as well as other additives. Furthermore, even if referred to as gold plating, Cu layer, nickel plating, etc., unless specifically indicated otherwise, it includes not only pure materials but also members with gold, Cu, nickel, etc. as the main component.

Moreover, when referring to specific numbers or quantities, unless clearly limited or obviously limited from the context, the specific numbers are described as examples.

In the drawings of the embodiments, the same or similar parts are denoted by the same or similar symbols or reference numerals, and the description will not be repeated in principle.

In addition, in the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. Furthermore, even if not in cross-section, hatching or dot patterns may be applied to clearly indicate that it is not a gap or to clearly indicate the boundary of a region.

### SEMICONDUCTOR DEVICE

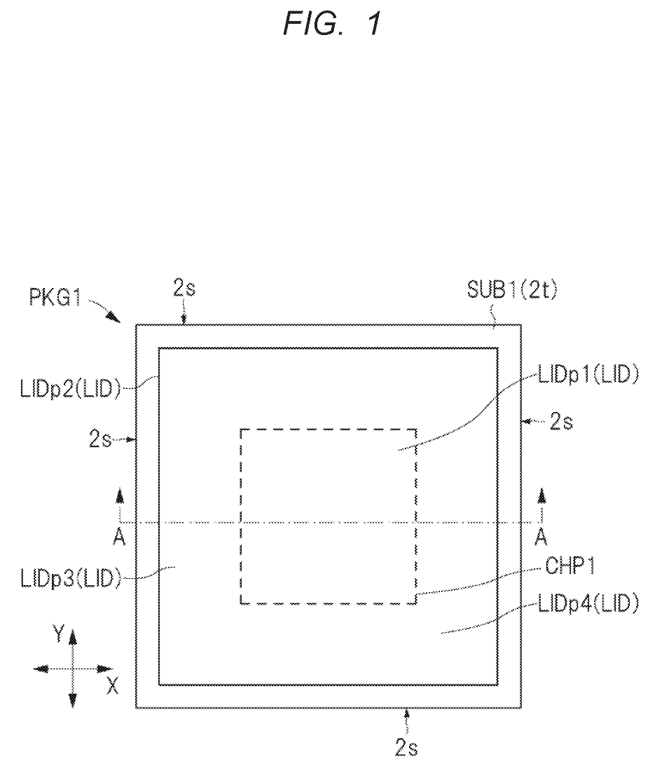

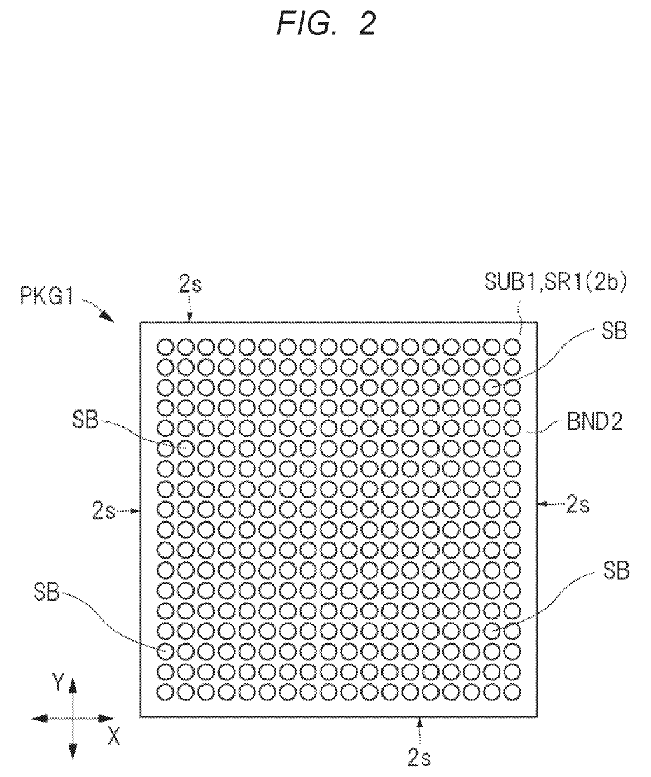

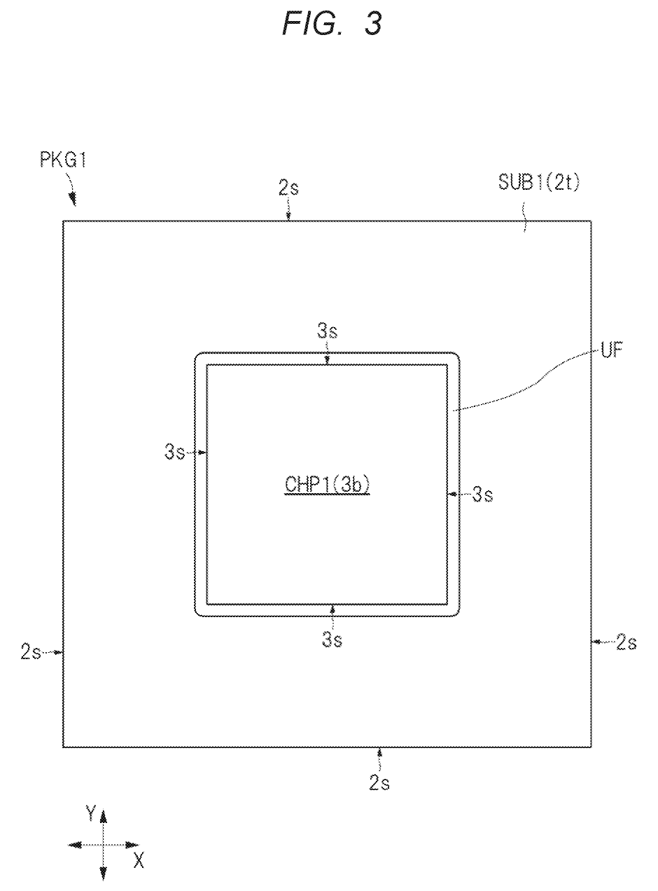

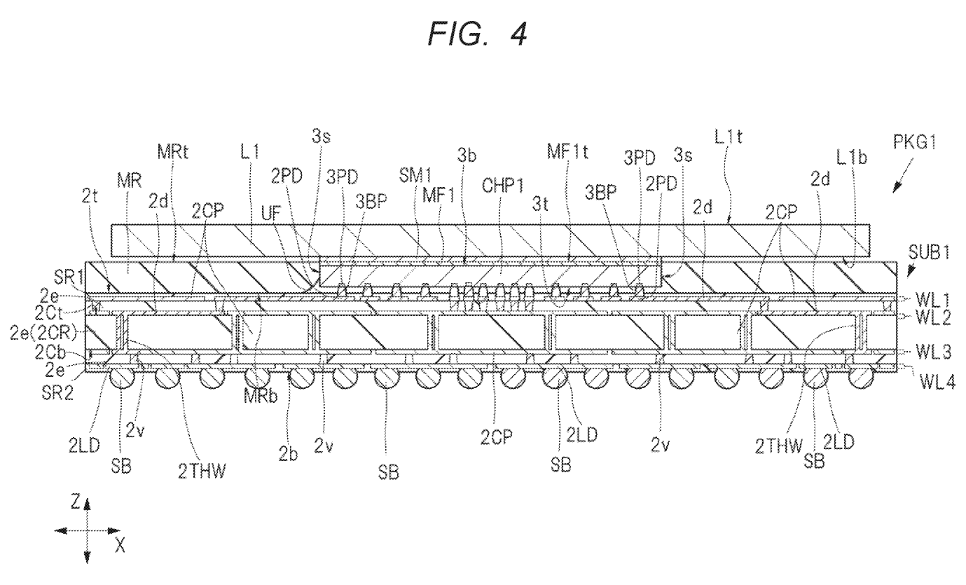

First, the semiconductor device of the present embodiment will be described. FIG. 1 is a top view of a semiconductor device according to one embodiment. FIG. 2 is a bottom view of the semiconductor device shown in FIG. 1. Also, FIG. 3 is a plan view showing the state where components and the sealing body on the semiconductor chip shown in FIG. 1 are removed. Also, FIG. 4 is a cross-sectional view along line A-A of FIG. 1. In FIG. 1, the outline of the semiconductor chip CHP1 covered by the metal plate (heat dissipation plate, lid) L1 is shown with a dotted line.

FIGS. 1 to 4 describe either the X direction (see FIGS. 1 to 4), the Y direction (see FIGS. 1, 2, and 3), or the Z direction (see FIG. 4). The Y direction is the direction intersecting the X direction, and in the following description, the X direction and Y direction are perpendicular to each other. The Z direction is the direction perpendicular to both the X direction and Y direction. In other words, the Z direction is the normal direction to the X-Y plane, which includes the X direction and Y direction (in other words, the vertical direction). In the following description, "thickness" generally means the length in the Z direction. Also, in the following description, "plan view" generally means the view of the X-Y plane.

The semiconductor device PKG1 of the present embodiment includes a wiring substrate SUB1 and a semiconductor chip CHP1 mounted on the wiring substrate SUB1 (see FIG. 3). As shown in FIG. 4, the semiconductor device PKG1 includes a sintered metal layer SM1 arranged via a metal film MF1 on the semiconductor chip CHP1, and a metal plate L1 covering the entire semiconductor chip CHP1. The metal plate L1 is fixed onto the back surface 3b of the semiconductor chip CHP1 via the sintered metal layer SM1 formed on the metal film MF1.

The wiring substrate SUB1 has an upper surface (surface, main surface, chip mounting surface) 2t on which the semiconductor chip CHP1 is mounted, and a lower surface (surface, main surface, mounting surface) 2b opposite the upper surface 2t. Furthermore, each of the upper surface 2t and lower surface 2b of the wiring substrate SUB1 has multiple sides 2s at the outer edge (see FIGS. 1 to 3). In the case of the present embodiment, the upper surface 2t (see FIG. 1) and lower surface 2b (see FIG. 2) of the wiring substrate SUB1 are each rectangular. The upper surface 2t is the chip mounting surface facing the front surface 3t of the semiconductor chip CHP1.

The wiring substrate SUB1 has a plurality of wiring layers that electrically connect the terminals (pads 2PD) on the upper surface 2t side, which is the chip mounting surface, and the terminals (lands 2LD) on the lower surface 2b side, which is the mounting surface. FIG. 4 illustrates a four-layer structure of wiring layers consisting of wiring layer WL1, wiring layer WL2, wiring layer WL3, and wiring layer WL4. Each wiring layer is located between the upper surface 2t and the lower surface 2b. Each wiring layer has conductor patterns such as wiring, which serve as paths for supplying electrical signals and power. Additionally, an insulating layer 2e is placed between each wiring layer. The multiple insulating layers 2e placed between each wiring layer include a core insulating layer (insulating layer, core material, insulating layer) 2CR, which is located between the upper surface 2t and the lower surface 2b. The core insulating layer 2CR is a core member to ensure the rigidity of the wiring substrate SUB1, and is made, for example, from prepreg impregnated with resin in glass fibers.

Each wiring layer is electrically connected to each other through interlayer conductive paths, which are via wiring 2v or through-hole wiring 2THW, penetrating the insulating layer 2e. In this embodiment, a wiring substrate with four wiring layers is illustrated as an example of the wiring substrate SUB1, but the number of wiring layers provided by the wiring substrate SUB1 is not limited to four. For example, a wiring substrate with three or fewer layers, or five or more layers, can be used as a modified example.

Among the plurality of wiring layers, the wiring layer WL1, which is positioned closest to the upper surface 2t, is covered by an insulating film SR1. An opening is provided in the insulating film SR1, and multiple pads 2PD provided on the wiring layer WL1 are exposed from the insulating film SR1 at the opening. Additionally, among the plurality of wiring layers, the wiring layer WL4, which is positioned closest to the lower surface 2b of the wiring substrate SUB1, is provided with multiple lands 2LD and is covered by an insulating film SR2. Each of the insulating films SR1 and SR2 is a solder resist film. Each of the multiple pads 2PD provided on the wiring layer WL1 and the multiple lands 2LD provided on the wiring layer WL4 is electrically connected through conductor patterns (wiring 2d and large-area conductor pattern 2CP), via wiring 2v, and through-hole wiring 2THW formed on each wiring layer provided by the wiring substrate SUB1.

Each of the wiring 2d, pads 2PD, via wiring 2v, via lands (not shown), through-hole lands (not shown), through-hole wiring 2THW, lands 2LD, and conductor pattern 2CP is made of a metal material, such as copper or a metal material with copper as the main component.

Additionally, the wiring substrate SUB1 is formed by laminating the plurality of wiring layers on the upper surface 2Ct and lower surface 2Cb of the core insulating layer (insulating layer, core material, core insulating layer) 2CR using a build-up method. Furthermore, the wiring layer WL2 on the upper surface 2Ct side of the core insulating layer 2CR and the wiring layer WL3 on the lower surface 2Cb side are electrically connected through multiple through-hole wiring 2THW embedded in multiple through-holes (through-holes) provided to penetrate from one side to the other of the upper surface 2Ct and lower surface 2Cb.

In the example shown in FIG. 4, each of the multiple lands 2LD is connected to a solder ball (solder material, external terminal, electrode, external electrode) SB. The solder ball SB is a conductive member that electrically connects multiple terminals (not shown) on the motherboard side and multiple lands 2LD when mounting the semiconductor device PKG1 on a motherboard (not shown).

As shown in FIG. 2, multiple solder balls SB are arranged in a matrix (array, matrix) form. Additionally, although not shown in FIG. 2, multiple lands 2LD (see FIG. 4) to which multiple solder balls SB are bonded are also arranged in a matrix (matrix) form.

As shown in FIG. 4, the semiconductor device PKG1 includes a semiconductor chip CHP1 mounted on the wiring substrate SUB1. The semiconductor chip CHP1 has a front surface (main surface, upper surface) 3t with multiple protruding electrodes 3BP arranged, and a back surface (main surface, lower surface) 3b opposite to the front surface 3t. Additionally, the semiconductor chip CHP1 has multiple side surfaces 3s. As shown in FIG. 3, the semiconductor chip CHP1 forms a rectangular outline shape with a smaller planar area than the wiring substrate SUB1 when viewed in plan. In the example shown in FIG. 3, the semiconductor chip CHP1 is mounted at the center of the upper surface 2t of the wiring substrate SUB1, and each of the four side surfaces 3s of the semiconductor chip CHP1 extends along each of the four sides 2s of the wiring substrate SUB1.

Additionally, multiple electrodes (pads, electrode pads, bonding pads) 3PD are arranged on the front surface 3t side of the semiconductor chip CHP1. In the example shown in FIG. 4, the semiconductor chip CHP1 is mounted on the wiring substrate SUB1 in such a state that the front surface 3t faces the upper surface 2t of the wiring substrate SUB1. Such a mounting method is called a face-down mounting method or a flip-chip connection method.

Although not shown, multiple semiconductor elements (circuit elements) are formed on the main surface of the semiconductor chip CHP1 (specifically, the semiconductor element formation region provided on the element formation surface of the semiconductor substrate, which is the base material of the semiconductor chip CHP1). The multiple electrodes 3PD are electrically connected to the multiple semiconductor elements through wiring (not shown) formed in the wiring layer placed inside the semiconductor chip CHP1 (specifically, between the front surface 3t and the semiconductor element formation region not shown).

An underfill resin (insulating resin, sealing body) UF is placed between the semiconductor chip CHP1 and the wiring substrate SUB1. The underfill resin UF is arranged to fill the space between the front surface 3t of the semiconductor chip CHP1 and the upper surface 2t of the wiring substrate SUB1. Each of the multiple protruding electrodes 3BP is sealed by the underfill resin UF.

In the case of the semiconductor device PKG1 according to this embodiment, the semiconductor chip CHP1 is sealed by the sealing body MR. The sealing body MR has a lower surface MRb facing the upper surface 2t of the wiring substrate SUB1 and an upper surface MRt located on the opposite side of the lower surface MRb.

Each of the multiple side surfaces 3s of the semiconductor chip CHP1 is covered by the sealing body MR. On the other hand, the back surface 3b of the semiconductor chip CHP1 is exposed from the sealing body MR. A part of the lower surface L1b of the metal plate L1 faces the upper surface MRt of the sealing body MR.

By being sealed by the sealing body MR, the semiconductor chip CHP1 can be protected. On the other hand, the back surface 3b of the semiconductor chip CHP1 is used as a heat dissipation path. Therefore, the back surface 3b of the semiconductor chip CHP1 needs to be exposed from the sealing body MR.

In the example shown in FIG. 4, the underfill resin UF and the sealing body MR are separate members. However, although not shown, as a modified example of the example shown in FIG. 4, there may be cases where the underfill resin UF is not used. That is, a part of the sealing body MR may be placed between the semiconductor chip CHP1 and the wiring substrate SUB1.

The sealing body MR may contain inorganic filler particles such as silica. If the gap between the front surface 3t and the upper surface 2t is narrow, it may be difficult to fill between the semiconductor chip CHP1 and the wiring substrate SUB1 depending on the diameter of the inorganic filler particles. Therefore, it is preferable that an underfill resin UF, which is easier to fill in narrow gaps compared to the sealing body MR, is filled between the semiconductor chip CHP1 and the wiring substrate SUB1.

### HEAT DISSIPATION PATH

Next, the heat dissipation path of the semiconductor device PKG1 will be described. In recent years, with the advancement of semiconductor devices, heat dissipation measures from semiconductor chips, which are the main heat sources during operation, have become important. In the case of the semiconductor device PKG1 shown in FIG. 4, it is necessary to suppress the temperature rise of the semiconductor chip CHP1 from the viewpoint of stabilizing the operation of the semiconductor chip CHP1. Therefore, it is preferable to efficiently release the heat generated by the semiconductor chip CHP1 to the outside.

In the case of the semiconductor device PKG1, the back surface 3b of the semiconductor chip CHP1 is thermally connected to the metal plate L1 through the metal film MF1 and the sintered metal layer SM1. This path functions as the main heat dissipation path of the semiconductor device PKG1. Therefore, to improve the heat dissipation characteristics of the semiconductor device PKG1, it is preferable to improve the thermal conductivity of each member constituting the main heat dissipation path.

In the case of the semiconductor device PKG1, since the semiconductor chip CHP1 and the metal plate L1 are thermally connected through the sintered metal layer SM1, the heat release characteristics of the heat generated by the semiconductor chip CHP1 can be improved. The metal plate L1 is a metal plate with higher thermal conductivity than the wiring substrate SUB1 and has the function of discharging the heat generated by the semiconductor chip CHP1 to the outside.

A metal film MF1 is placed on the back surface 3b of the semiconductor chip CHP1. The metal film MF1 is a metal thin film formed by metallizing the back surface 3b. As a method for forming the metal thin film, which is the metal film MF1, deposition methods using physical vapor deposition (PVD) or chemical vapor deposition (CVD) can be exemplified.

The metal film MF1 may consist of a single element or may be made of an alloy containing multiple types of elements. Additionally, the metal film MF1 may be a single-layer metal film or may consist of a laminated film of two or more layers.

Examples of metals constituting the metal film MF1 include gold, silver, copper, or copper alloy. If the metal film MF1 is a laminated film, the top layer film with the upper surface MF1t of the metal film MF1 consists of, for example, gold, silver, copper, or copper alloy.

When the metal film MF1 is electrically connected to the circuit of the semiconductor chip CHP1, the metal film MF1 can be used as an electrode (i.e., back electrode) of the semiconductor chip CHP1. However, in the present embodiment, the metal film MF1 is electrically separated from the circuit provided in the semiconductor chip CHP1.

As shown in FIG. 4, the semiconductor device PKG1 is connected to the semiconductor chip CHP1 and the metal plate L1 via the sintered metal layer SM1. For example, it is difficult to directly form the sintered metal layer SM1 on the back surface 3b of the semiconductor chip CHP1 made of silicon. On the other hand, in the present embodiment, the entire back surface 3b is covered with the metal film ML1. The metal film ML1 and the sintered metal layer SM1 can be easily bonded. As a result, the connection reliability of the connection interface between the sintered metal layer SM1 and the semiconductor chip CHP1 can be improved.

The sintered metal layer SM1 is a metal layer composed of multiple metal particles bonded together. Metal particles are made of silver, for example. As a method of fixing the metal plate L1 on the semiconductor chip CHP1, a method using a resin adhesive layer is available. Additionally, as a method to improve the thermal conductivity characteristics of the resin adhesive layer, there is a method of filling the resin with high thermal conductivity fillers such as metal particles. However, even with the method of filling the resin with fillers, there is a limit to the improvement effect of the thermal conductivity of the resin adhesive layer. For example, the thermal conductivity of resin adhesive layers sold as heat dissipation sheets is about 10 W/mK.

In the present embodiment, the sintered metal layer SM1 is used as an intermediate member for fixing the semiconductor chip CHP1 and the metal plate L1. In this case, compared to using a resin adhesive layer as an intermediate member, the heat transfer efficiency can be improved. For example, the thermal conductivity of silver is 428 W/mK. The thermal conductivity of sintered silver varies with its density, but it is possible to easily achieve a thermal conductivity of 100 W/mK or more.

The semiconductor chip CHP1 is covered by a metal plate (lid) L1. The metal plate L1 has a lower surface L1b facing the back surface 3b of the semiconductor chip CHP1, and an upper surface L1t on the opposite side of the lower surface L1b. The lower surface L1b of the metal plate L1 is bonded to the sintered metal layer SM1.

The metal plate L1 functions as a heat dissipation path to suppress the temperature rise of the semiconductor chip CHP1. The metal plate L1 is a heat dissipation member made of metal with high thermal conductivity. The metal plate L1 is made of copper, for example. However, there are various modifications to the material constituting the metal plate L1. For example, the metal plate L1 may be made of stainless steel.

In the present embodiment, the metal plate L1 is a flat plate-like member. Therefore, the metal plate L1 is fixed onto the wiring substrate SUB1 via the semiconductor chip CHP1 and is not adhered to the upper surface 2t of the wiring substrate SUB1.

The thermal conductivity of the metal plate L1 is higher than the thermal conductivity of the semiconductor substrate provided in the semiconductor chip CHP1, for example. Although not shown, as a method of dissipating heat via the metal plate L1, in addition to dissipating heat externally from the metal plate L1 itself, there may be cases where heat dissipation members such as heat dissipation fins are attached on the metal plate L1.

### METHOD OF MANUFACTURING SEMICONDUCTOR DEVICE

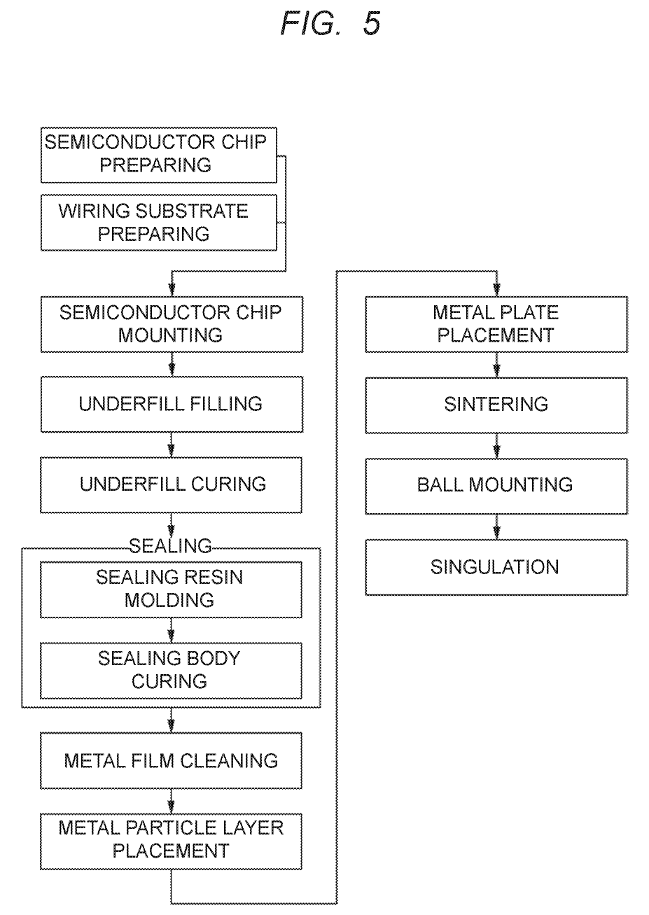

Next, a method of manufacturing a semiconductor device will be described. FIG. 5 is an explanatory diagram showing an example of the manufacturing process of the semiconductor device manufacturing method shown in FIG. 1. The method of manufacturing the semiconductor device according to the present embodiment includes each step illustrated in FIG. 5.

### SEMICONDUCTOR CHIP PREPARING STEP

The method of manufacturing the semiconductor device according to the present embodiment includes a semiconductor chip preparing step. In the semiconductor chip preparing step, the semiconductor chip CHP1 shown in FIG. 4 is prepared. The semiconductor chip CHP1 has a front surface 3t on which a plurality of protruding electrodes 3BP is arranged, and a back surface 3b opposite to the front surface 3t. Additionally, a metal film MF1 is pre-formed on the back surface 3b.

The method for forming the metal film MF1 can use the deposition method such as PVD or CVD, as already described. The entire back surface 3b of the semiconductor chip CHP1 is covered with the metal film MF1.

### WIRING SUBSTRATE PREPARING STEP

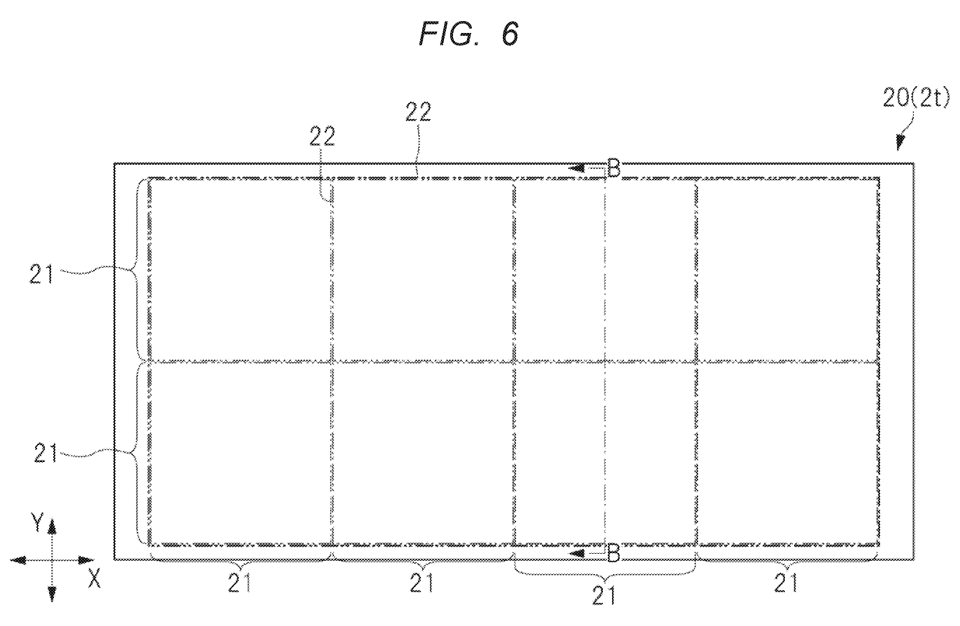

The method of manufacturing the semiconductor device according to the present embodiment includes a wiring substrate preparing step. In the wiring substrate preparing step, the wiring substrate 20 shown in FIG. 6 is prepared. FIG. 6 is a plan view showing an example of the wiring substrate prepared in the wiring substrate preparing step shown in FIG. 5.

The wiring substrate 20 shown in FIG. 6 is a so-called multi-piece substrate in which a plurality of device regions 21 is provided. The upper surface 2t of the wiring substrate 20 has the plurality of device regions 21 and a dicing region 22 surrounding each of the plurality of device regions 21. Each of the plurality of device regions 21 corresponds to the wiring substrate SUB1 shown in FIG. 4. Therefore, if the plurality of device regions 21 is individualized along the dicing region 22, the wiring substrate SUB1 shown in FIG. 4 can be obtained. The cross-sectional structure of each device region 21 is similar to the wiring substrate SUB1 already described using FIG. 4, so redundant explanations are omitted.

When manufacturing the semiconductor device using the wiring substrate 20, each of the underfill curing step, the sealing resin molding step, the sealing body curing step, the metal film cleaning step, and the sintering step shown in FIG. 5 can be efficiently implemented. This is because the plurality of device regions 21 can be processed collectively.

As a modified example of the present embodiment, in this step, the wiring substrate SUB1 shown in FIG. 4 may be prepared. In this case, the singulation step shown in FIG. 5 can be omitted.

### SEMICONDUCTOR CHIP MOUNTING STEP

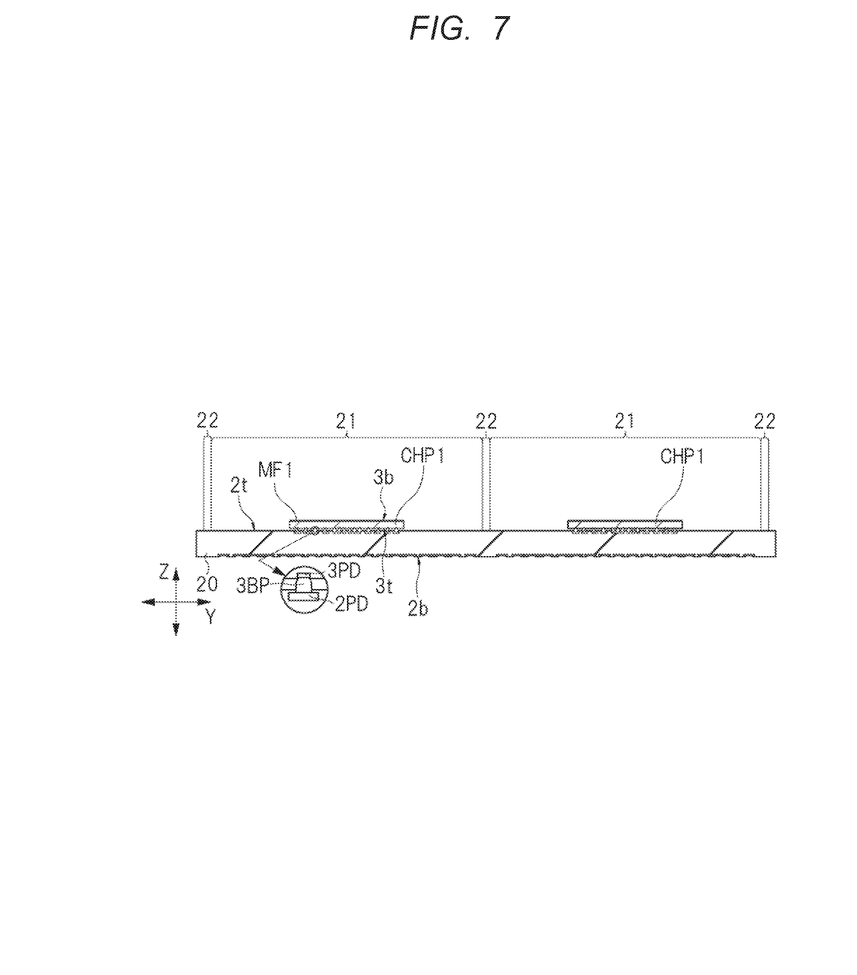

The method of manufacturing the semiconductor device according to the present embodiment includes a semiconductor chip mounting step. In the semiconductor chip mounting step, the semiconductor chip CH1 is mounted on the upper surface 2t of the wiring substrate 20 as shown in FIG. 7. FIG. 7 is a cross-sectional view showing the state where the semiconductor chip is mounted on the wiring substrate in the semiconductor chip mounting step shown in FIG. 5. The cross-section of FIG. 7 matches the cross-section along the B-B line shown in FIG. 6. Additionally, in FIG. 7, the detailed structure of the plurality of wiring layers shown in FIG. 4 is omitted.

In the semiconductor chip mounting step, the semiconductor chip CHP1 is mounted on the wiring substrate 20 such that the front surface 3t faces the upper surface 2t of the wiring substrate 20. Each of the plurality of electrodes 3PD of the semiconductor chip CHP1 is arranged in a position respectively facing the plurality of pads 2PD of the wiring substrate 20. After placing the semiconductor chip CHP1 on the wiring substrate 20, by performing a reflow treatment, the plurality of electrodes 3PD and the plurality of pads 2PD are electrically connected, respectively, via the protruding electrodes 3BP. Such a connection method is called a flip-chip connection method, and the semiconductor chip mounting step of the present embodiment is called a face-down mounting method, where the front surface 3t of the semiconductor chip CHP1 faces the upper surface 2t of the wiring substrate 20.

### UNDERFILL FILLING STEP

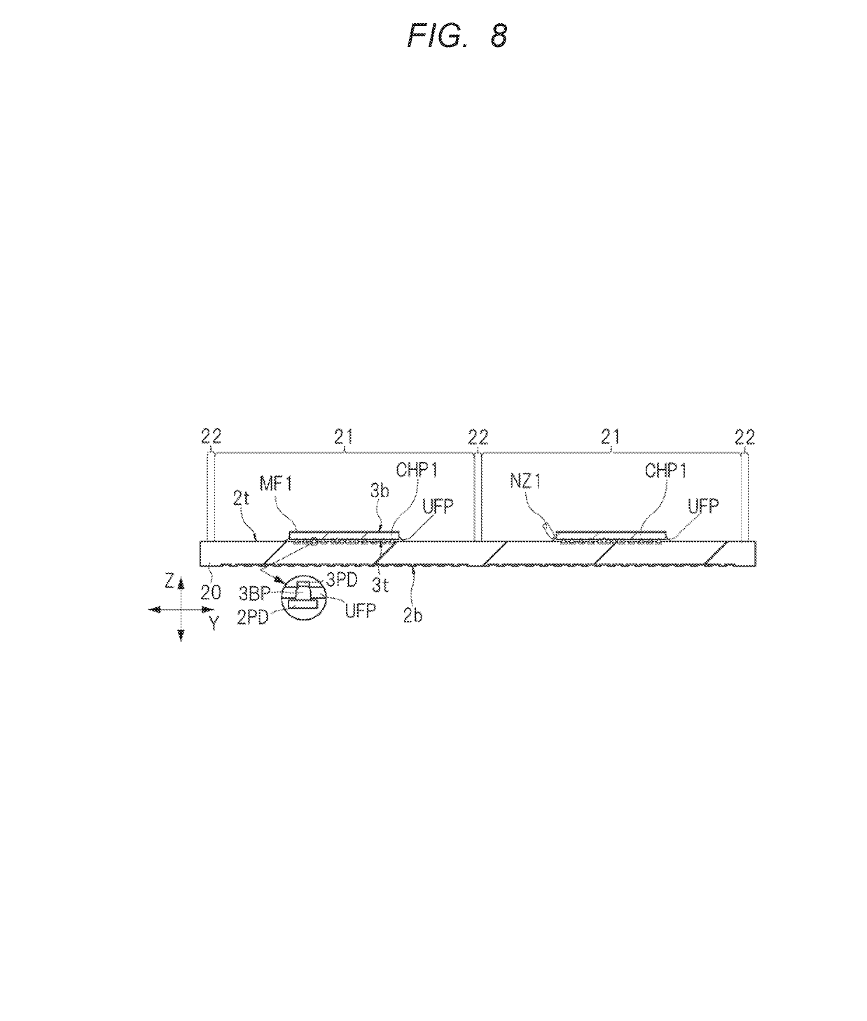

The method of manufacturing the semiconductor device according to the present embodiment includes an underfill filling step. In the underfill filling step, as shown in FIG. 8, an underfill paste UFP is filled in the gap between the upper surface 20t of the wiring substrate 20 and the front surface 3t of the semiconductor chip CHP1. FIG. 8 is a cross-sectional view showing the state where the underfill paste is filled between the semiconductor chip and the wiring substrate in the underfill filling step shown in FIG. 5.

As shown in FIG. 8, the underfill paste UFP is discharged from the nozzle NZ1 toward the gap between the semiconductor chip CHP1 and the wiring substrate 20. Between the semiconductor chip CHP1 and the wiring substrate 20, a plurality of protruding electrodes 3BP is arranged. The underfill paste UFP discharged from the nozzle NZ1 progresses through the gap between the semiconductor chip CHP1 and the wiring substrate 20 due to capillary action and reaches the opposite side of the nozzle NZ1.

### UNDERFILL CURING STEP

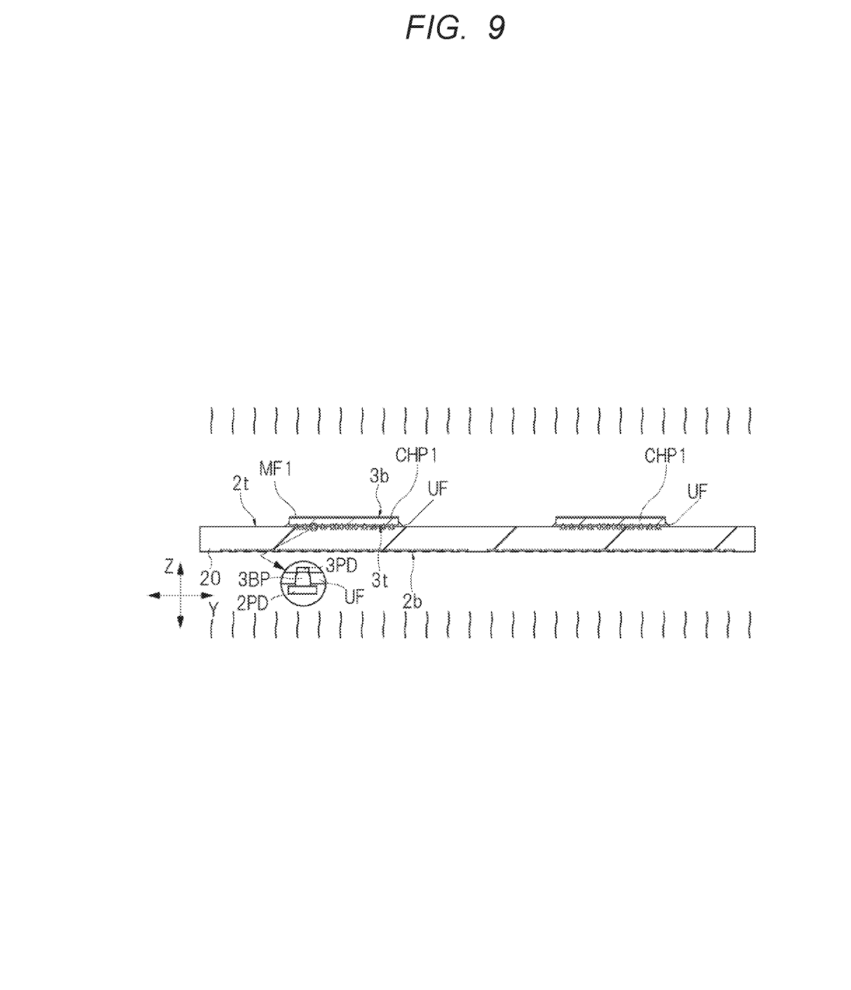

The method of manufacturing the semiconductor device according to the present embodiment includes an underfill curing step. In the underfill curing step, the underfill paste UFP shown in FIG. 8 is cured to form the underfill resin UF shown in FIG. 9. FIG. 9 is a schematic cross-sectional view showing the state where the underfill paste is being cured in the underfill curing step shown in FIG. 5.

In FIG. 9, a method of heat curing is illustrated as an example of the step for curing the underfill paste UFP (see FIG. 8). The underfill paste UFP contains, for example, thermosetting resin. The condition for the heat treatment (called underfill cure) to cure the underfill paste UFP is, for example, placing the wiring substrate 20 supplied with the underfill paste UFP in a heating furnace at 170 degrees Celsius to 185 degrees Celsius for 2 hours. As a result, the thermosetting resin component contained in the underfill paste UFP is cured, and the underfill resin UF shown in FIG. 9 is obtained.

In this step, the front surface 3t of the semiconductor chip CHP1 and each of the plurality of protruding electrodes 3BP arranged on the front surface 3t are sealed with the underfill resin UF. The underfill resin UF is a sealing body that seals the front surface 3t of the semiconductor chip CHP1 and each of the plurality of protruding electrodes 3BP.

If the separation distance between the front surface 3t of the semiconductor chip CHP1 and the upper surface 2t of the wiring substrate 20 is sufficiently large, and the sealing resin can be supplied between the semiconductor chip CHP1 and the wiring substrate 20 in the sealing resin molding step described later, the underfill filling step and the underfill curing step can be omitted.

However, in general, in the case of a semiconductor device where the semiconductor chip CHP1 is mounted using a face-down mounting method, the separation distance between the semiconductor chip CHP1 and the wiring substrate 20 is small. Therefore, it is preferable to carry out the underfill filling step and the underfill curing step as in the present embodiment.

### SEALING STEP

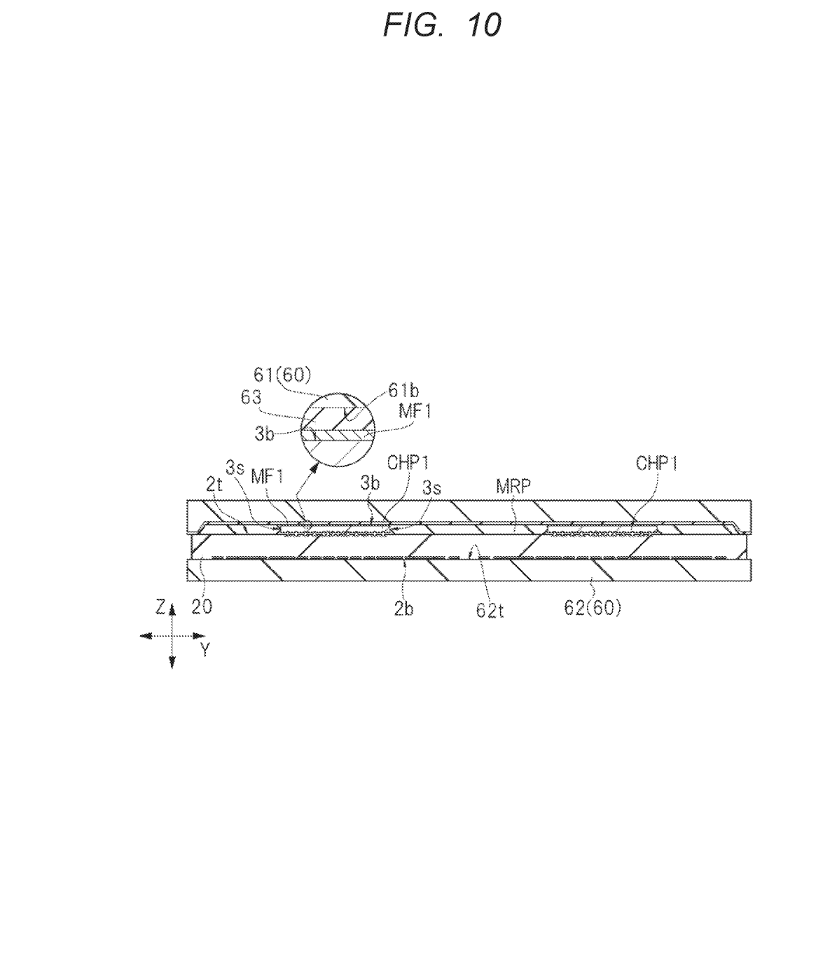

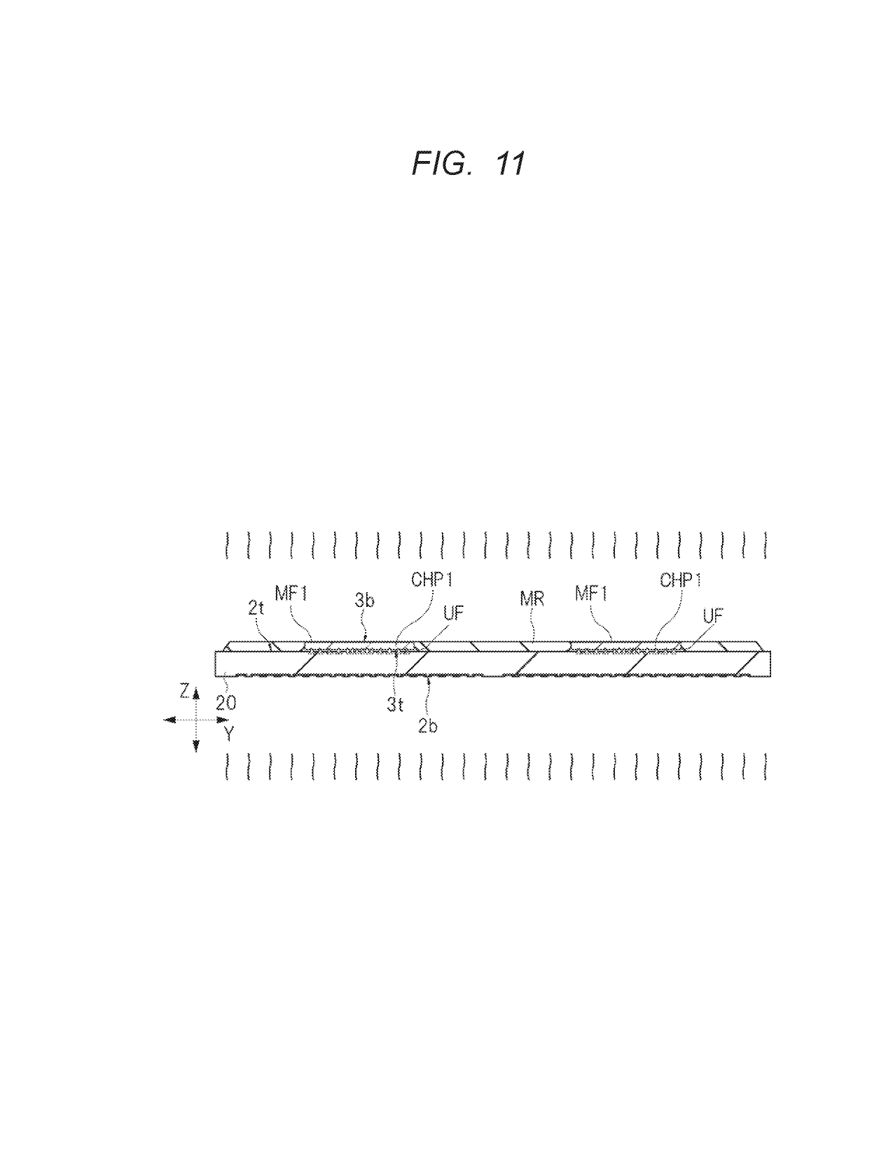

The method of manufacturing the semiconductor device according to the present embodiment includes a sealing step. The sealing step includes a sealing resin molding step and a sealing body curing step. FIG. 10 is a cross-sectional view showing the state in which the sealing resin is filled in the molding die where the wiring substrate shown in FIG. 9 is placed, in the sealing resin molding step shown in FIG. 5. FIG. 11 is a schematic cross-sectional view showing the state in which the sealing resin shown in FIG. 10 is cured to form the sealing body, in the sealing resin molding step shown in FIG. 5.

In the present embodiment, the sealing body MR shown in FIG. 11 is formed by transfer molding using the molding die 60 shown in FIG. 10. Also, in the case of the present embodiment, the sealing body MR is formed such that the metal film MF1 is exposed. When the sealing step is completed, the upper surface 2t of the wiring substrate 20 and the side surface 3s of the semiconductor chip CHP1 are covered with the sealing body MR.

The molding die 60 shown in FIG. 10 has an upper molding die 61 and a lower molding die 62. A cavity is formed in the upper molding die 61. In the case of the present embodiment, the sealing body MR is formed on the upper surface 2t of the wiring substrate 20. Therefore, the cavity is not formed in the lower molding die 62, but is selectively formed in the upper molding die 61. The upper molding die 61 and the lower mold die 62 face each other through the cavity of the upper mold die 61.

In the sealing resin molding step, first, the wiring substrate 20 is placed in the cavity of the upper molding die 61 of the molding die 60 shown in FIG. 10. The semiconductor chip CHP1 is already mounted on the wiring substrate 20, and the underfill resin UF (see FIG. 9) is formed.

Next, the wiring substrate 20 is clamped between the upper molding die 61 and the lower molding die 62. As a result, the lower surface 2b of the wiring substrate 20 adheres closely to the upper surface 62t of the lower molding die 62.

In the case of the present embodiment, the sealing body MR is formed such that the metal film MF1 is exposed, as described above. In other words, in this step, the semiconductor chip CHP1 and the upper surface 2t of the wiring substrate 20 are covered with the sealing resin MRP such that the metal film MF1 is exposed. To ensure that the entire upper surface of the metal film MF1 is exposed, it is necessary to prevent the sealing resin MRP from entering between the upper molding die 61 and the metal film MF1 when filling the sealing resin MRP.

Therefore, in the present embodiment, as shown in FIG. 10, the sealing resin MRP is filled in such a state that a sheet (resin sheet) 63 is interposed between the metal film MF1 and the lower surface 61b of the upper molding die 61. The sheet 63 is, for example, a resin sheet. The sheet 63 is an elastic body that is more easily elastically deformed than the upper mold 61 and the metal film MF1. Therefore, the sheet 63 easily adheres to the metal film MF1, preventing the sealing resin MRP from entering between the upper molding die 61 and the metal film MF1 during the sealing resin molding step.

The sealing resin MRP contains thermosetting resin and has fluidity. The sealing resin MRP may contain filler materials such as silica. The sealing resin MRP may contain black pigment.

The sealing resin MRP filled in the molding die 60 is molded following the shape of the cavity. Maintaining the sealing resin MRP in the cavity in a heated state allows a part of the thermosetting resin contained in the sealing resin MRP to cure, enabling the sealing resin MRP to be temporarily cured. The temporarily cured sealing resin MRP has shape retention properties. Therefore, even if the temporarily cured sealing resin MRP is removed from the molding die 60, it can maintain the molded shape as shown in FIG. 11.

Next, in the sealing body curing step, the sealing resin MRP shown in FIG. 10 is fully cured by heating the sealing resin MRP, and the sealing body MR shown in FIG. 11 is formed. In other words, in the sealing body curing step, the heat treatment is applied to the sealing resin MRP to form the sealing body MR. The condition for the heat treatment (called “mold cure”) to cure the sealing resin MRP is, for example, placing the wiring substrate 20 covered with the sealing resin MRP in a heating furnace at 175 degrees Celsius for 4 hours. As a result, the thermosetting resin components contained in the sealing resin MRP are fully cured, and obtaining the sealing body MR shown in FIG. 11.

### METAL FILM CLEANING STEP

The method of manufacturing the semiconductor device according to the present embodiment includes a metal film cleaning step.

As shown in FIG. 11, in the sealing body curing step, the metal film MF1 is subjected to a high-temperature atmosphere for a long time while the metal film MF1 is exposed from the sealing body MR. Therefore, by the time that the sealing body curing step is completed, the state of the outermost surface (exposed surface) of the metal film MF1 may have changed from the state immediately after the formation of the metal film MF1.

For example, if the outermost surface (exposed surface) of the metal film MF1 is made of copper or copper alloy, the outermost surface of the metal film MF1 may be oxidized by contact with the atmosphere in a high-temperature environment, forming an oxide film. Additionally, some components contained in the sealing body MR may evaporate (called outgassing) and then re-condense, adhering to the outermost surface of the metal film MF1. This phenomenon, where substances adhere to the outermost surface of the metal film MF1 due to outgassing, is called “contamination of metal film MF1 due to outgassing”.

Also, for example, if the outermost surface (exposed surface) of the metal film MF1 is made of gold or silver, it is less likely to form an oxide film compared to when it is made of copper or copper alloy. However, the “contamination of metal film MF1 due to outgassing” as described above may occur.

As already explained, the metal film ML1 and the sintered metal layer SM1 shown in FIG. 4 can be easily bonded. However, if the outermost surface of the metal film ML1 is contaminated, the bonding ability between the metal film ML1 and the sintered metal layer SM1 may decrease.

Therefore, before forming the sintered metal layer SM1 on the metal film ML1, it is preferable to clean the outermost surface of the metal film ML1 and remove the oxide film or contaminants. As shown in FIG. 5, in the case of the present embodiment, the metal film cleaning step is carried out after the sealing step and before the metal particle layer placement step.

In the metal film cleaning step, the surface of the metal film MF1 is cleaned. For example, if the outermost surface of the metal film MF1 is made of silver or gold, this step removes substances adhering to the outermost surface of the metal film MF1 due to gas generated from the sealing body MR in the sealing step.

Also, for example, if the outermost surface of the metal film MF1 is made of copper or copper alloy, this step removes substances adhering to the outermost surface of the metal film MF1 due to gas generated from the sealing body MR in the sealing step and also removes the oxide film formed on the metal film MF1.

The cleaning method can include chemical cleaning method, plasma cleaning method, or combinations of these. In the chemical cleaning method, the cleaning liquid containing chemicals is brought into contact with the outermost surface of the metal film MF1, which is the surface to be cleaned, to chemically remove substances from the outermost surface. As a cleaning liquid, for example, an alcohol-based cleaning liquid containing a chelating agent can be used. In the case of this cleaning liquid, the chelating effect can remove the copper oxide film. Additionally, substances adhering to the metal film MF1 can also be removed with the aforementioned cleaning liquid. Therefore, if the outermost surface of the metal film MF1 is any of silver, gold, copper, or copper alloy, it can be cleaned using the above cleaning liquid.

In the plasma cleaning step, plasma is irradiated onto the outermost surface of the metal film MF1, which is the surface to be cleaned, to physically remove substances from the outermost surface. In this method, by controlling the input voltage when generating plasma or the plasma irradiation time, the oxide film or substances adhering to the outermost surface can be removed.

### METAL PARTICLE LAYER PLACEMENT STEP

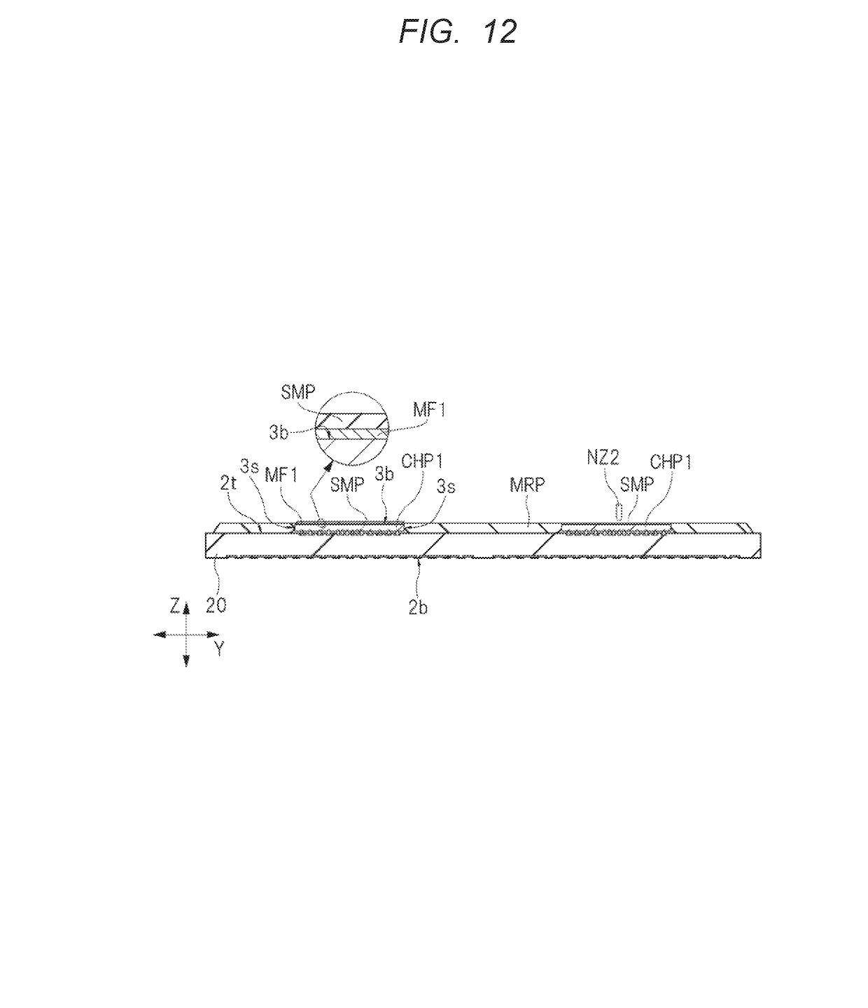

The method of manufacturing the semiconductor device according to the present embodiment includes a metal particle layer placement step. FIG. 12 is a cross-sectional view showing the state in which a metal particle paste is placed on the metal film in the metal particle layer placement step shown in FIG. 5. In this step, as shown in FIG. 12, a metal particle layer SMP containing a plurality of metal particles is placed on the metal film MF1 exposed from the sealing body MR.

The metal particle layer SMP is, for example, a paste material containing the plurality of metal particles in a paste-like organic material. The plurality of metal particles is, for example, a silver particle. When using a paste-like metal particle layer SMP, in this step, the paste-like metal particle layer SMP is applied or printed on the metal film MF1.

As a variation of the metal particle layer SMP, a sheet material pre-formed into a sheet shape may be used. The sheet material contains the plurality of metal particles and is made of binder resin pre-formed into a sheet shape. The metal particles are, for example, silver particles. When using sheet material, in this step, the sheet-shaped metal particle layer SMP is placed on the metal film MF1.

The plurality of metal particles contained in the metal particle layer SMP is sintered in the sintering step shown in FIG. 5. Additionally, the organic material or binder resin containing the plurality of metal particles evaporates in the sintering step.

### METAL PLATE PLACEMENT STEP

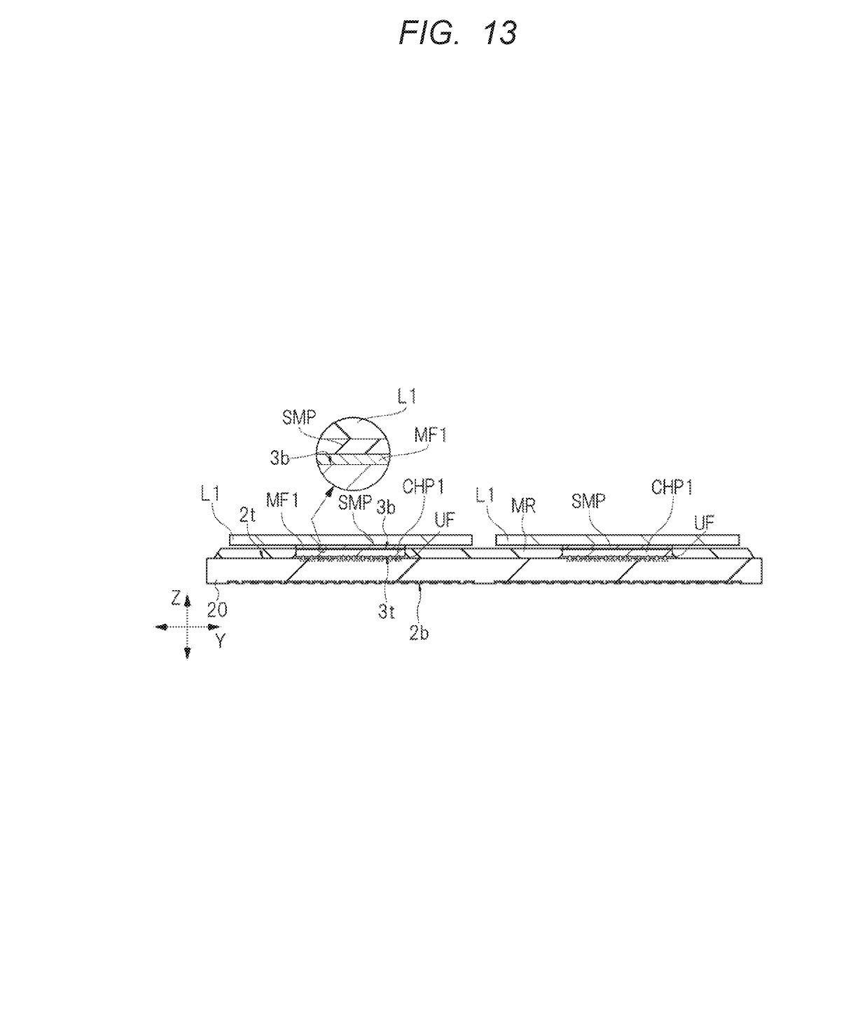

The method of manufacturing the semiconductor device according to the present embodiment includes a metal plate placement step. FIG. 13 is a cross-sectional view showing the state in which a metal plate is placed on a metal particle layer before sintering in the metal plate placement step shown in FIG. 5. In this step, as shown in FIG. 13, the metal plate L1 is placed on the metal particle layer SMP.

As shown in FIG. 5, the metal plate placement step is carried out before the sintering step. At this stage of the process, the metal particle layer SMP contains organic material components. Therefore, when the metal plate L1 is placed on the metal particle layer SMP, the metal plate L1 is adhered to the metal particle layer SMP.

In this step, there is a method of pressing the metal plate L1 against the metal particle layer SMP (in other words, pressurizing the metal particle layer SMP). However, from the viewpoint of preventing the metal particle layer SMP from spreading widely, for example, on the sealing body MR, it is preferable in this step not to pressurize the metal particle layer SMP, but simply to place the metal plate L1 on the metal particle layer SMP. Even in this case, the shape of the metal particle layer SMP is flattened by the weight of the metal plate L1.

### SINTERING STEP

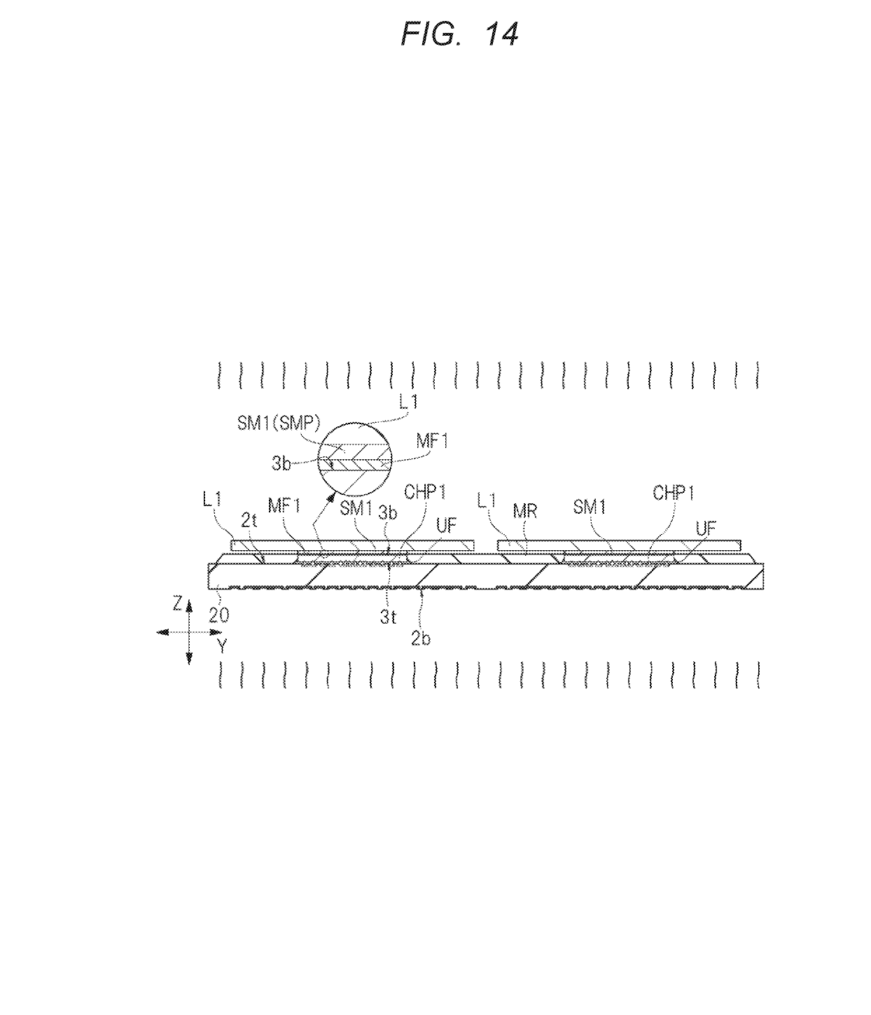

The method of manufacturing the semiconductor device according to this embodiment includes a sintering step. FIG. 14 is a schematic cross-sectional view showing the state in which the metal particle layer SMP is heated to form a sintered layer in the sintering step shown in FIG. 5. In this step, as shown in FIG. 14, by heating the metal particle layer SMP, the plurality of metal particles is sintered to form the sintered metal layer SM1. In other words, in the sintering step, the metal particle layer SMP is performed to the heat treatment to form the sintered metal layer SM1.

In the sintering step, the plurality of metal particles contained in the metal particle layer SMP is heated. As a result, adjacent metal particles are sintered, and the sintered metal layer SM1 is formed. Also, in this step, the organic components contained in the metal particle layer SMP evaporate. The sintering temperature is higher than the temperature of the mold cure in the sealing step, but the heating time is shorter than the time of the mold cure in the sealing step. The heat treatment condition of this sintering step is, for example, heating the wiring substrate 20, on which the metal plate L1 is placed via the metal particle layer SMP, in a heating furnace at a temperature of 200 degrees Celsius to 250 degrees Celsius for about 1 hour to 2 hours.

In the case of this embodiment, as mentioned above, it includes the metal film cleaning step. Therefore, at the time of starting the sintering step, the oxide film or contaminants on the metal film ML1 have been removed in advance. As a result, when the sintering step is completed, the bonding interface between the sintered metal layer SM1 and the metal film MF1 is bonded in a good condition.

### BALL MOUNTING STEP

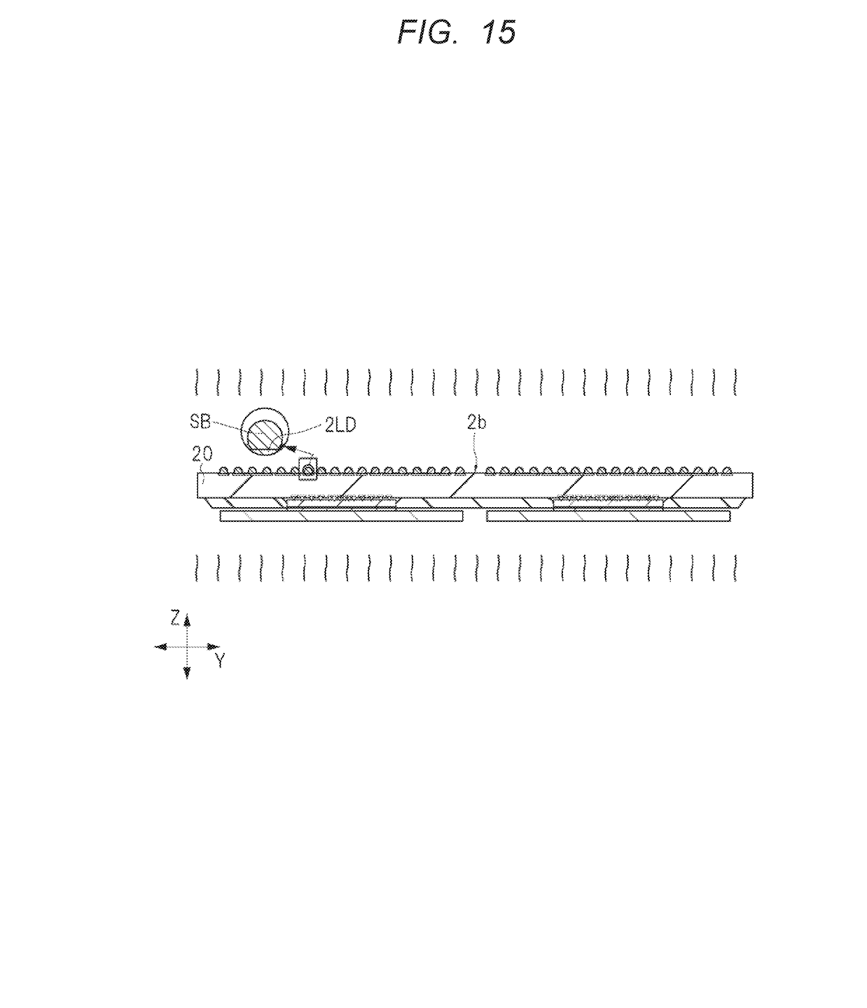

The method of manufacturing the semiconductor device according to this embodiment includes a ball mounting step. FIG. 15 is a schematic cross-sectional view showing the state in which a solder ball is placed on the land of the wiring substrate in the ball mounting step shown in FIG. 5, followed by a reflow treatment.

In this step, a plurality of lands 2LD of the wiring substrate 20 shown in FIG. 15 and a plurality of solder balls SB are respectively bonded. After placing the solder ball SB on each of the plurality of lands 2LD exposed on the lower surface 2b of the wiring substrate 20, the reflow treatment is performed. By heating the solder balls SB to above their melting point and then cooling them, the solder ball is bonded to the land 2LD. The temperature of the reflow treatment is, for example, 240 degrees Celsius, and the heating time is about 20 seconds to 100 seconds.

To activate a surface of the solder ball, there may be a case where the solder ball SB is reflowed while the solder ball SB is in contact with flux. Alternatively, as a modified example of this step, there may be a case where a solder material containing solder components and flux components, called solder paste, is applied. In either method, due to the surface tension of the solder components, the solder material forms into a ball shape on the land 2LD, resulting in the plurality of solder balls SB as shown in FIG. 2.

The flux components used to activate the surface of the solder material may remain as residue around the solder ball SB by the reflow treatment. In this case, although not shown in FIG. 5, it is preferable to add a cleaning step after the solder ball formation step to remove the residue of the flux components.

### SINGULATION STEP

The method of manufacturing the semiconductor device according to this embodiment includes the semiconductor chip mounting step. When using the multi-piece substrate such as the wiring substrate 20, as shown in FIG. 5, a singulation step is performed after the ball mounting step. In the singulation step, the wiring substrate 20 is cut along the dicing region 22 shown in FIG. 6, and the plurality of device regions 21 is divided into multiple pieces. The cutting method is not particularly limited, but for example, a method of cutting the wiring substrate 20 using a dicing blade (not shown) can be exemplified. In the wiring substrate preparing step shown in FIG. 5, when preparing the wiring substrate SUB1 shown in FIGS. 1 to 4, the singulation step can be omitted. This is because the wiring substrate SUB1 shown in FIGS. 1 to 4 corresponds to one device region 21 shown in FIG. 6.

### FIRST MODIFIED EXAMPLE

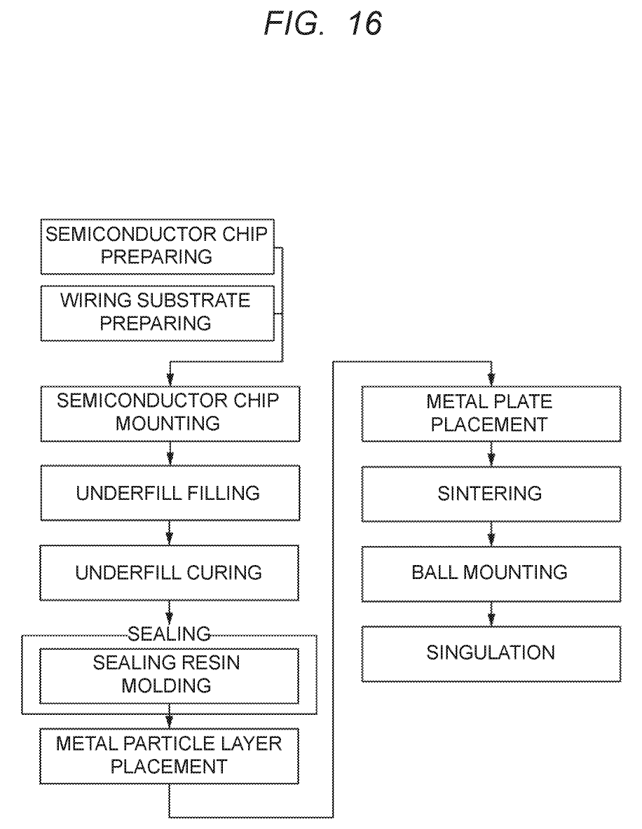

Next, a modified example of the above-described method of manufacturing the semiconductor device will be explained. Below, the differences from the method of manufacturing the semiconductor device explained using FIG. 5 will be described, and overlapping explanations will be omitted in principle. FIG. 16 is an explanatory diagram showing a modified example of the method of manufacturing the semiconductor device shown in FIG. 5. The method of manufacturing the semiconductor device shown in FIG. 16 differs from the method of manufacturing the semiconductor device shown in FIG. 5 in the following points.

First, in the modified example shown in FIG. 16, the sealing body curing step shown in FIG. 5 is omitted in the sealing step. In other words, in this modified example, in the sealing resin molding step, after the sealing resin MRP (see FIG. 10) is temporarily cured, the metal particle layer placement step is carried out before the sealing resin MRP is fully cured.

Also, this modified example differs from the method of manufacturing the semiconductor device shown in FIG. 5 in that it omits the metal film cleaning step shown in FIG. 5.

In this modified example, the metal particle layer placement step is carried out before performing the aforementioned mold cure. Therefore, even if the metal film cleaning step explained using FIG. 5 is omitted, contamination and oxidation of the metal film MF1 (see FIG. 12) can be suppressed.

In this modified example, the underfill curing step is also carried out. However, in the underfill curing step, the influence of outgassing as in the aforementioned sealing body curing step is hardly observed. In this modified example, compared to the method of manufacturing the semiconductor device shown in FIG. 5, the number of manufacturing processes can be reduced. Therefore, manufacturing efficiency can be improved.

If the outermost surface (exposed surface) of the metal film MF1 (see FIG. 12) is made of copper or a copper alloy, an oxide film may be formed on the outermost surface of the metal film MF1. Therefore, from the viewpoint of improving the manufacturing efficiency of the semiconductor device, it is preferable to use gold or silver as the metal film MF1.

In this modified example, most of the thermosetting resin contained in the sealing resin MRP is cured (for example, 70% or more) while the wiring substrate 20 is placed in the cavity of the upper molding die 61 of the molding die 60 shown in FIG. 10. Therefore, even if the sealing resin MRP is in a temporarily cured state, it can be handled.

Also, in this modified example, the full curing of the sealing resin MRP is carried out in the sintering step. That is, in the sintering step shown in FIG. 16, by heating the sealing resin MRP, the sealing body MR is cured, and by heating the metal particle layer SMP (see FIG. 14), it is sintered to form the sintered metal layer SM1 (see FIG. 14). The example of each of the sintering temperature and sintering time is the same as the conditions already described.

In this modified example, the mold cure is not carried out before the sintering step. Therefore, when the sintering step is completed, the bonding interface between the sintered metal layer SM1 and the metal film MF1 is bonded in good condition.

The method of manufacturing the semiconductor device shown in FIG. 16 is the same as the method of manufacturing the semiconductor device explained using FIG. 5, except for the differences mentioned above. Therefore, overlapping explanations are omitted.

### SECOND MODIFIED EXAMPLE

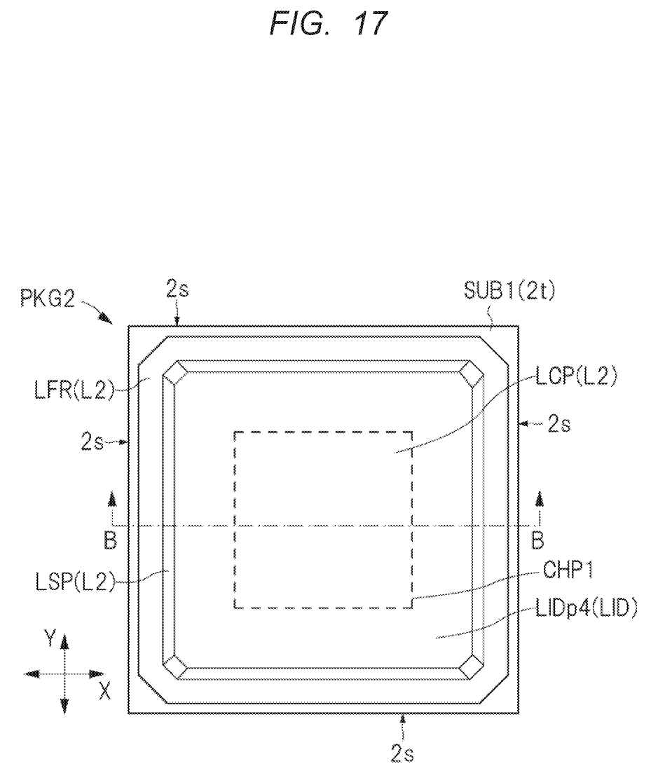

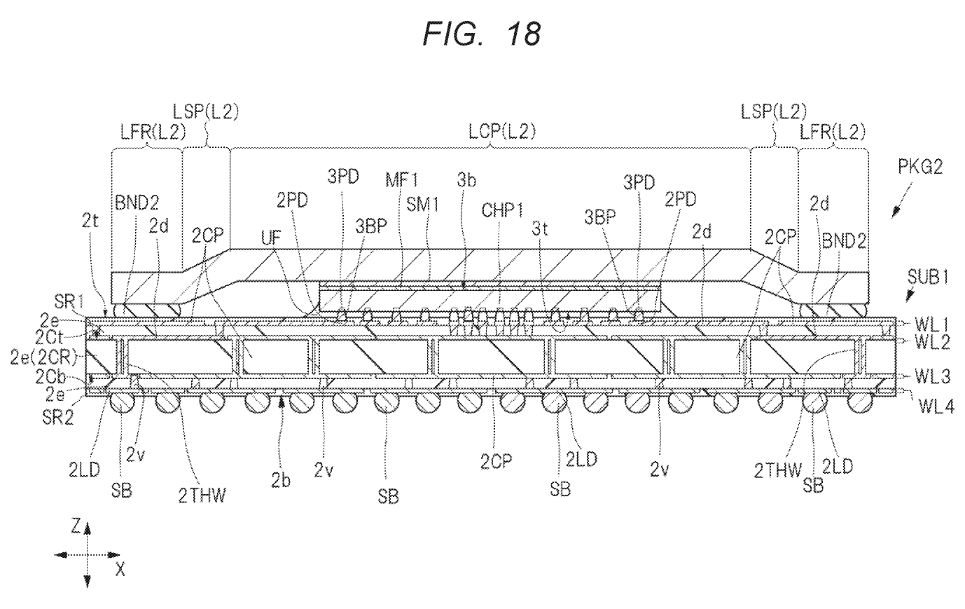

Next, a modified example of the semiconductor device shown in FIGS. 1 to 4 will be explained. Below, the differences from the semiconductor device explained using FIGS. 1 to 4 will be described, and overlapping explanations will be omitted in principle. FIG. 17 is a top view of a semiconductor device as a modification of FIG. 1. FIG. 18 is a cross-sectional view along the line B-B of FIG. 17.

The semiconductor device PKG2 shown in FIGS. 17 and 18 has a metal plate L2 whose shape differs from the metal plate L1 of the semiconductor device PKG1 shown in FIGS. 1 to 4.

As shown in FIGS. 17 and 18, the metal plate L2 includes a flange portion LFP, a cover portion LCP, and a support portion LSP. The flange portion LFP is adhered to the upper surface 2t of the wiring substrate SUB1 via the sintered metal layer SM1 (see FIG. 18). The cover portion LCP is positioned above the semiconductor chip CHP1 and is fixed onto the semiconductor chip CHP1 via the metal film MF1 and the sintered metal layer SM1. The support portion LSP connects the flange portion LFP and the cover portion LCP. The support portion LSP is a member for supporting the cover portion LCP, which is positioned higher than the flange portion LFP.

To efficiently function the metal plate L2 as a heat dissipation path, it is necessary to thermally connect the semiconductor chip CHP1 and the metal plate L2. In this modification, the cover portion LCP of the metal plate L2 and the back surface 3b of the semiconductor chip CHP1 are thermally connected via the metal film MF1 and the sintered metal layer SM1, which have high thermal conductivity.

The heat dissipation path of the semiconductor device PKG2 is mainly a path from the back surface 3b of the semiconductor chip CHP1 to the metal plate L2 via the metal film MF1 and the sintered metal layer SM1. Therefore, high thermal conductivity is not required for the adhesive layer BND2. The adhesive layer BND2 can be freely selected within the range where the adhesive strength with the wiring substrate SUB1 is ensured. For this reason, the thermal conductivity of the adhesive layer BND2 is lower than that of the sintered metal layer SM1.

The adhesive layer BND2 is comprised of, for example, a resin adhesive containing a thermosetting resin component. Alternatively, a conductive paste mixed with metal particles such as silver filler in a resin paste may be used as the material for the adhesive layer BND2.

The method of manufacturing the semiconductor device PKG2 differs from the method of manufacturing the semiconductor device shown in FIG. 5 in the following points. First, the method of manufacturing the semiconductor device PKG2 does not include a sealing step. This is because, as shown in FIG. 18, it does not have a sealing body MR that seals the semiconductor chip CHP1. In this modified example, since the sealing step is not performed, the issue of contamination of the outermost surface of the metal film MF1 due to the influence of the aforementioned outgas does not occur. Therefore, the metal film cleaning step shown in FIG. 5 can be omitted.

However, if the metal film MF1 is made of copper or copper alloy, an oxide film may be formed on the outermost surface of the metal film MF1 during the heat treatment in the underfill curing step. Therefore, when using copper or copper alloy as the metal film MF1, it is preferable to perform the metal film cleaning step to improve the bonding strength between the metal film MF1 and the sintered metal layer SM1.

Furthermore, the semiconductor device PKG2 according to this modified example differs from the semiconductor device PKG1 shown in FIG. 4 in that the flange portion LFP of the metal plate L2 is adhered to the upper surface 2t of the wiring substrate SUB1 via the adhesive layer BND2. Therefore, the method of manufacturing the semiconductor device PKG2 in this modified example includes a step of placing an adhesive on the upper surface 2t of the wiring substrate SUB1 before the metal plate placement step shown in FIG. 5. The adhesive layer BND2 can be cured during the heat treatment in the sintering step shown in FIG. 5.

The semiconductor device PKG2 according to this modified example is similar to the semiconductor device PKG1 and the method of manufacturing described using FIGS. 1 to 15, except for the differences mentioned above. Therefore, redundant explanations are omitted.

Although not shown, in the sealing body MR (see FIG. 4) as in this modified example, a flat plate member without the flange portion LFP (see FIG. 17) and the support portion FSP (see FIG. 17) as shown in the metal plate L1 in FIG. 4 may be used.

In this case, it is possible to mount electronic components such as chip capacitors between the peripheral portion of the metal plate L1 and the wiring substrate SUB1 (see FIG. 17). Also, for example, if the size of the metal plate L1 is approximately the same as the size of the back surface 3b (see FIG. 18) of the semiconductor chip CHP1 (see FIG. 18), the planar size of the semiconductor package can be reduced.

Although the invention made by the present inventor has been specifically described based on the embodiment, the present invention is not limited to the above embodiment, and it is needless to say that various modifications can be made without departing from the gist thereof.

For example, the above-mentioned multiple modified examples may be combined with each other.

What is claimed is:

1. A semiconductor device comprising:
a wiring substrate having a first surface;
a semiconductor chip having a second surface and a third surface opposite the second surface, the semiconductor chip being mounted on the wiring substrate such that the second surface faces the first surface; and
a first metal plate fixed onto the third surface of the semiconductor chip,
wherein the semiconductor chip includes:
a plurality of protruding electrodes arranged on the second surface; and
a first metal film formed on the third surface, and
wherein the first metal plate is fixed onto the third surface of the semiconductor chip via a sintered metal layer formed on the first metal film.

2. The semiconductor device according to claim 1, further comprising:
a first sealing body that seals the plurality of protruding electrodes; and
a second sealing body that seals a side surface of the semiconductor chip,
wherein the first metal film is exposed from the second sealing body.

3. The semiconductor device according to claim 2, wherein the first metal plate is fixed onto the wiring substrate via the semiconductor chip and is not adhered to the first surface of the wiring substrate.

4. A method of manufacturing a semiconductor device, comprising steps of:
(a) preparing a wiring substrate having a first surface;
(b) after the step of (a), mounting a semiconductor chip on the wiring substrate such that a second surface of the semiconductor chip faces the first surface of the wiring substrate, the semiconductor chip having the second surface, a plurality of protruding electrodes arranged on the second surface, a third surface opposite the second surface, and a first metal film formed on the third surface;
(c) after the step of (b), covering the semiconductor chip and the first surface of the wiring substrate with a sealing resin such that the first metal film is exposed from the sealing resin;
(d) after the step of (c), performing a heat treatment on the sealing resin, and forming a sealing body;
(e) after the step of (d), placing a metal particle layer containing a plurality of metal particles on the first metal film exposed from the sealing body; and
(f) after the step of (e), placing a first metal plate on the metal particle layer.

5. The method according to claim 4, further comprising:
(g) after the step of (f), performing a heat treatment on the metal particle layer, and forming a sintered metal layer.

6. The method according to claim 5, further comprising:
(h) after the step of (d) and before the step of (e), cleaning a surface of the first metal film.

7. The method according to claim 6,
wherein an outermost surface of the first metal film is made of silver or gold; and
wherein, in the step of (h), a substance adhering to the outermost surface of the first metal film due to a gas generated from the sealing body in the step of (d) is removed.

8. The method according to claim 6,
wherein an outermost surface of the first metal film is made of copper or copper alloy; and
wherein, in the step of (h), a substance adhering to the outermost surface of the first metal film due to a gas generated from the sealing body in the step of (d) is removed, and an oxide film formed on the first metal film is removed.

9. The method according to claim 4, wherein the step of (c) includes:
(c1) placing the wiring substrate on which the semiconductor chip is mounted in a cavity of a molding die;
(c2) placing a resin sheet on the first metal film; and
(c3) supplying a resin into the cavity in such a state that the resin sheet is interposed between the first metal film and the molding die, and molding the sealing body following a shape of the cavity.

10. A method of manufacturing a semiconductor device, comprising steps of:
(a) preparing a wiring substrate having a first surface;
(b) after the step of (a), mounting a semiconductor chip on the wiring substrate such that a second surface of the semiconductor chip faces the first surface of the wiring substrate, the semiconductor chip having the second surface, a plurality of protruding electrodes arranged on the second surface, a third surface opposite the second surface, and a first metal film formed on the third surface;
(c) after the step of (b), covering the semiconductor chip and the first surface of the wiring substrate with a sealing resin such that the first metal film is exposed from the sealing resin;
(d) after the step of (c) and before fully curing the sealing resin, placing a metal particle layer containing a plurality of metal particles on the first metal film exposed from the sealing resin;
(e) after the step of (d), placing a first metal plate on the metal particle layer; and
(f) after the step of (e), performing a heat treatment on the sealing resin and the metal particle layer so as to fully cure the sealing resin, and forming a sealing body and a sintered metal layer.
